(19) United States
(12) Patent Application Publication
(10) Pub. No.: US 2009/0153217 A1
(43) Pub. Date: Jun. 18, 2009

(54) Active Clamp Switching Circuit

(76) Inventors: Tsun-Hsiao HSIA, Taipei Hsien (TW); Chung-Ping KU, Taipei Hsien (TW)

Correspondence Address: TROXELL LAW OFFICE PLLC;ONE SKYLINE PLACE, SUITE 1404, 5205 LEESBURG PIKE, FALLS CHURCH, VA, 22041, US

(21) Appl. No.: 12/271,582

(22) Filed: Nov. 14, 2008

(30) Foreign Application Priority Data
May 8, 2007 (TW) 096207320
Nov. 15, 2007 (TW) 096219278

(51) Int. Cl. H03K 5/08

(52) U.S. Cl. 327/321

(57) ABSTRACT

An active clamp switching circuit includes a transformer having a primary winding and a secondary winding, a first switch, a capacitor, an impedance device, a second switch and a rectifier. The capacitor, the impedance device and the second switch form a reset loop for the primary winding so that the impedance device lowers the electric current going through the second switch, preventing burnout of the second switch.

### BACKGROUND OF THE INVENTION

1. Field of the Invention

The present invention relates generally to a switching circuit and more particularly, to an active clamp switching circuit that has an impedance connected in series to the reset loop of the primary winding to lower the value of the current going through the switch, preventing burnout of the switch.

2. Description of the Related Art

FIG. 1 is a block diagram of a forward converter. As illustrated, the forward converter comprising a transformer 100 having a primary winding 101 and a secondary winding 102, a switch 110, an active clamp switch 120 having a body diode 121, a capacitor 130, and a leakage inductance 103 connected between the primary winding 101 and the capacitor 130.

When the aforesaid switch 110 is off, the storage energy of the leakage inductance 103 is charged through the reset loop formed of the active clamp switch 120 and the capacitor 130, thereby zeroing the potential.

The maximum current the body diode 121 of the active clamp switch 120 can sustain is

$$( Io\_max \cdot n + \frac{Vin}{Lm + Lr} \cdot D \cdot Ts ) ,$$

however, under over current protection (OCP) or over load protection (OLP), a big CCM (continue conductive mode) current (Io_ocp·n) goes through the transformer 100 and a spike occurs at the active clamp switch 120 when the switch 110 is off. This spike may surpass the rated current of the active clamp switch, causing the active clamp switch to burn out. Some measures may be employed and intended to prevent the aforesaid problem. One measure is known to connect a bead coil in series to the connection between the active clamp switch 120 and the capacitor 130 in order to increase the loop impedance and to further lower the current going therethrough. Another measure is known to connect a shocky diode in parallel to the source and drain of the active clamp switch 120. When the voltage surpassed the reverse conduction voltage of the shocky diode, the shocky diode breaks down (shorts the circuit), lower the value of the current going through the active clamp switch 120. In actual practice, the effectiveness of either of the aforesaid measures is insignificant. They cannot effectively lower the value of the current going through the active clamp switch 120 to prevent the active clamp switch from burning out.

Therefore, it is desirable to provide a boostbuck circuit that eliminates the aforesaid problem.

### SUMMARY OF THE INVENTION

The present invention has been accomplished under the circumstances in view. It is the main object of the present invention to provide an active clamp switching circuit that has an impedance connected in series to the reset loop of the primary winding to lower the value of the current going through the switch, preventing burnout of the switch.

To achieve this and other objects of the present invention, the active clamp switching circuit comprises a transformer, which comprises a primary winding and a secondary winding, the primary winding having a first end coupled to the non-inverter terminal of a power source and a second end opposite to the first end of the primary winding, a first switch, which is a TRIAC having a first end coupled to the second end of the primary winding and a second end coupled to a first control signal and a third end coupled to the inverter terminal of the power source of which the non-inverter terminal is coupled to the primary winding, a capacitor, which has a first end coupled to the first end of the primary winding and a second end opposite to the first end of the capacitor, an impedance device, which has a first end coupled to the second end of the capacitor and a second end opposite to the first end of the impedance device, a second switch, which is a TRIAC having a first end coupled to the second end of the impedance device and a second end coupled to a second control signal and a third end coupled to the first end of the first switch, and a rectifier, which has one end coupled to the connection between the capacitor and the impedance device and an opposite end coupled to the first end of the first switch. The capacitor and the impedance and the second switch form a reset loop for the primary winding so that the impedance device lowers the electric current going through the second switch, preventing burnout of the second switch.

### BRIEF DESCRIPTION OF THE DRAWINGS

FIG. 1 is a circuit block diagram of a forward converter according to the prior art.

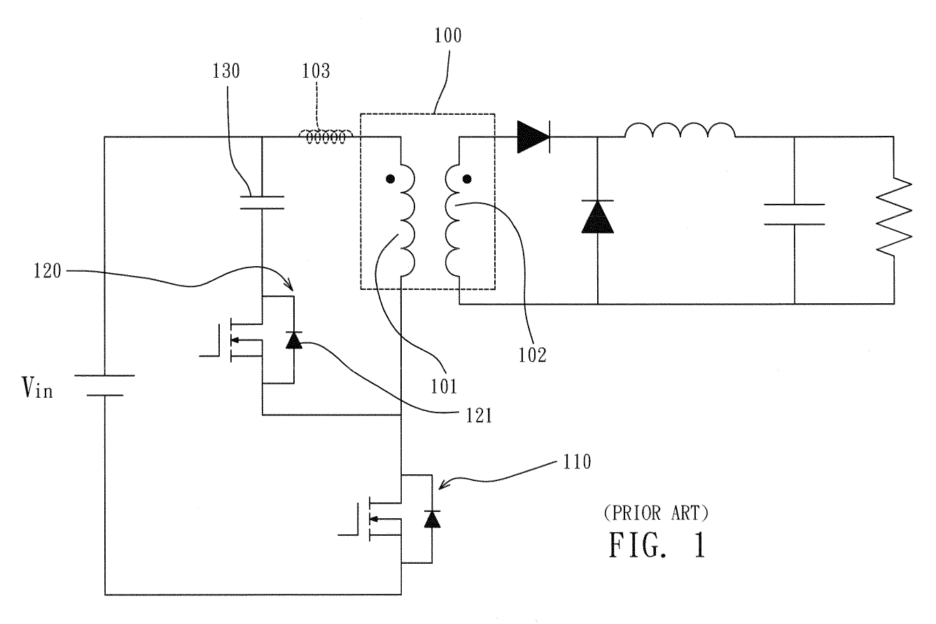

FIG. 2 is a circuit block diagram of an active clamp switching circuit according to the present invention.

### DETAILED DESCRIPTION OF THE INVENTION

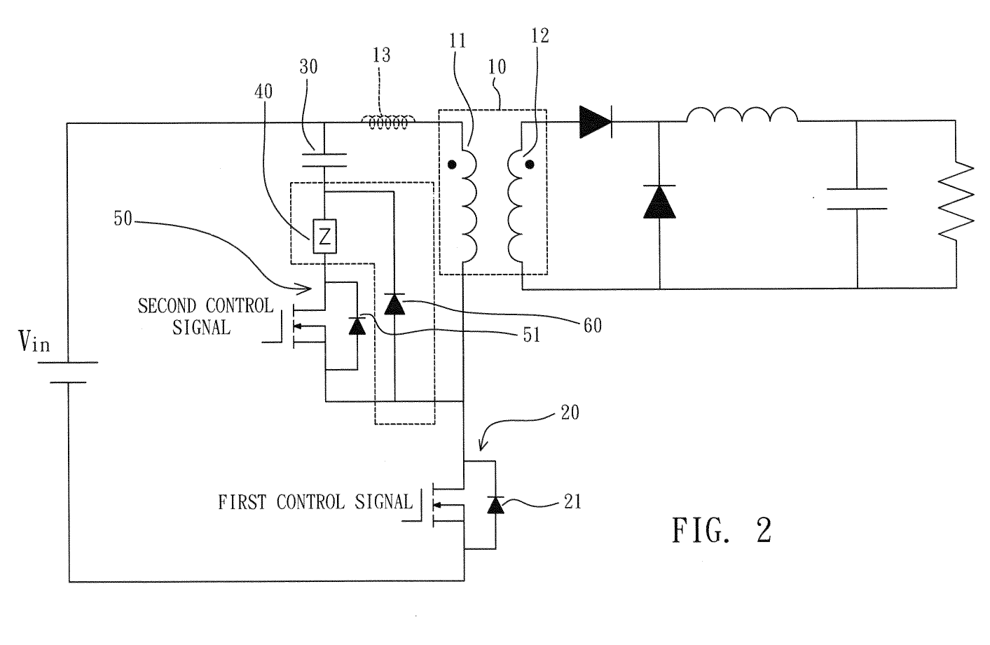

FIG. 2 is a circuit block diagram of an active clamp switching circuit. As illustrated, the active clamp switching circuit comprises a transformer 10, a first switch 20, a capacitor 30, an impedance device 40, a second switch 50, and a rectifier 60.

The transformer 10 comprises a primary winding 11, a secondary winding 12, and a leakage inductance 13. The primary winding 11 has one end coupled to the non-inverter input terminal of a power source (Vin). The transformer 10 can be, but not limited to, a forward converter. As a forward converter is a known product, no further detailed description in this regard is necessary.

The first switch 20 is a TRIAC that can be any power switch, for example, but not limited to, an N-pass MOSFET (metal-oxide semiconductor field-effect transistor), N-pass junction field-effect transistor, P-pass MOSFET or P-pass junction field-effect transistor. The first switch 20 hereinafter is referred to as a first MOSFET. The first MOSFET 20 has a first end coupled to the other end of the primary winding 11, a second end coupled to a first control signal, and a third end coupled to the inverter input terminal of the power source (Vin). The first end of the first MOSFET 20 is the drain. The second end of the first MOSFET 20 is the gate. The third end of the first MOSFET 20 is the source. The first MOSFET 20 further comprises a body diode 21. The first control signal can be, but not limited to, a pulse width modulation signal.

The capacitor 30 has one end coupled to one end of the primary winding 11, thereby constituting with the impedance device 40, the second switch 50 and the primary winding 11 a reset loop.

The impedance device 40 has one end coupled to the other end of the capacitor 30 to increase the impedance of the reset loop and to reduce the current passing through the second switch 50, preventing burnout of the second switch 50. The impedance device 40 can be, but not limited to, a resistor or bead coil. According to the present preferred embodiment, the impedance device 40 is a resistor.

The second switch 50 is a TRIAC for uses an active clamp switch. It can be, but not limited to, N-pass MOSFET (metal-oxide semiconductor field-effect transistor), N-pass junction field-effect transistor, P-pass MOSFET or P-pass junction field-effect transistor. The second switch 50 hereinafter is referred to as a second MOSFET. The second MOSFET 50 has a first end coupled to the other end of the impedance device 40, a second end coupled to a second control signal, and a third end coupled to the first end of the first switch. The first end of the second MOSFET 50 is the drain. The second end of the second MOSFET 50 is the gate. The third end of the second MOSFET 50 is the source. The second MOSFET 50 further comprises a body diode 51. The second control signal can be, but not limited to, a reverse pulse width modulation signal. An external controller can be used to control the delay time of the reverse pulse width modulation signal, preventing conduction the reverse pulse width modulation signal with the pulse width modulation signal of the first control signal at a same time.

The rectifier 60 has one end coupled to the connection between the capacitor 30 and the impedance device 40, and an opposite end coupled to the first end of the first switch 20. The rectifier 60 can be a diode or power switch. Preferably, the rectifier 60 is formed of a diode for the advantage of low cost.

When the first switch 20 is off, the storage energy of the leakage inductance 13 is discharged through two paths, one path goes through the rectifier 60 and the capacitor 30, and the other path goes through the second switch 50, the impedance device 40 and the capacitor 30. The path going through the rectifier has a relatively lower impedance for the passing of a relatively greater current. The path going through the second switch 50 and the impedance device 40 has a relatively higher impedance for the passing of a relatively smaller current. When an electric current is going through the impedance device 40, the voltage drop at the impedance device 40 enables a big amount of current to go through the rectifier 60, thereby assuring that the current goes through the body diode 51 of the second switch 50 is lower than the rated value of the second switch 50, and therefore zero potential is achieved without causing burning of the second switch 50. Thus, the improvement of the active clamp switching circuit of the present invention is superior to prior art design, satisfying inventive step.

As stated above, the active clamp switching circuit of the present invention has an impedance device connected in series to the reset loop of the first winding to lower the value of the current going through the active clamp switch, preventing burnout of the active clamp switch. Therefore, the invention satisfies inventive step.

Although a particular embodiment of the invention has been described in detail for purposes of illustration, various modifications and enhancements may be made without departing from the spirit and scope of the invention. Accordingly, the invention is not to be limited except as by the appended claims.

What is claimed is:

1. An active clamp switching circuit comprising:
a transformer, said transformer comprising a primary winding and a secondary winding, said primary winding having a first end coupled to the non-inverter input terminal of a power source and a second end opposite to the first end of said primary winding;
a first switch, said first switching being a TRIAC having a first end coupled to the second end of said primary winding and a second end coupled to a first control signal and a third end coupled to the inverter input terminal of the power source of which the non-inverter terminal is coupled to said primary winding;
a capacitor, said capacitor having a first end coupled to the first end of said primary winding and a second end opposite to the first end of said capacitor;
an impedance device, said impedance device having a first end coupled to the second end of said capacitor and a second end opposite to the first end of said impedance device;
a second switch, said second switch being a TRIAC having a first end coupled to the second end of said impedance device and a second end coupled to a second control signal and a third end coupled to the first end of said first switch; and
a rectifier, said rectifier having one end coupled to the connection between said capacitor and said impedance device and an opposite end coupled to the first end of said first switch;
wherein said capacitor and said impedance and said second switch form a reset loop for said primary winding so that said impedance device lowers the electric current going through said second switch to prevent burn-out of said second switch.

2. The active clamp switching circuit as claimed in claim 1, wherein said transformer is a forward transformer.

3. The active clamp switching circuit as claimed in claim 1, wherein said first switch and said second switch are power switches respectively prepared from one of N-pass MOSFET (metal-oxide semiconductor field-effect transistor), N-pass junction field-effect transistor, P-pass (metal-oxide semiconductor field-effect transistor) and P-pass junction field-effect transistor.

4. The active clamp switching circuit as claimed in claim 3, wherein said first switch and said second switch are metal-oxide semiconductor field-effect transistors; and the first end, second end and third end of each of said first switch and said second switch are the drain, gate and source of the respective metal-oxide semiconductor field-effect transistor.

5. The active clamp switching circuit as claimed in claim 1, wherein said first switch comprises a body diode.

6. The active clamp switching circuit as claimed in claim 1, wherein said second switch comprises a body diode.

7. The active clamp switching circuit as claimed in claim 1, wherein said rectifier is a diode.

8. The active clamp switching circuit as claimed in claim 1, wherein said impedance is a resistor.

9. The active clamp switching circuit as claimed in claim 1, wherein said impedance is a bead coil.

10. The active clamp switching circuit as claimed in claim 1, wherein said first control signal is a pulse width modulation signal; said second control signal is a reverse pulse width modulation signal.
